(19) United States
(12) Patent Application Publication
(10) Pub. No.: US 2003/0221313 A1
(43) Pub. Date: Dec. 4, 2003

(54) Method for making stacked integrated circuits (ICs) using prepackaged parts

(76) Inventor: Keith D. Gann, Tustin, CA (US)

Correspondence Address: Joseph C. Andras, MYERS, DAWES & ANDRAS LLP, 19900 MacArthur Blvd, Ste 1150, Irvine, CA, 92612, US

(21) Appl. No.: 10/339,023

(22) Filed: Jan. 9, 2003

Related U.S. Application Data
(63) Continuation-in-part of application No. 09/770,864, filed on Jan. 26, 2001.
(60) Provisional application No. 60/346,494, filed on Jan. 9, 2002.

(51) Int. Cl. H05K 3/34; H01R 9/00; H01H 1/00

(52) U.S. Cl. 29/840; 29/841; 29/855; 29/827; 29/843; 29/593; 174/250; 174/260

(57) ABSTRACT

A method of making a stacked assembly of integrated circuits (ICs) from prepackaged semiconductor chips is disclosed. The method involves the steps of first starting with a commercially available prepackaged semiconductor chip (e.g. a thin small outline package (TSOP)), that contains bare silicon die within an encapsulant and removing at least part of the encapsulant from the lateral sides to expose the wire bonds. More such prepackaged chips are modified and stacked upon one another. Metalization is performed on the stack to interconnect the layers. An additional embodiment discloses the use of lead frames to the stack of integrated circuits. Additional disclosure covers a method of stacking printed circuit boards (PCBs). A compact and low cost mini-computer is also disclosed that is made using methods of the present invention.

### RELATED APPLICATIONS

The present application is related to U.S. Provisional Patent Application serial No. 60/346,494, filed on Jan. 9, 2002, which is incorporated herein by reference and to which priority is claimed pursuant to 35 USC 119, and is a continuation-in-part of U.S. patent application Ser. No. 09/770,864, filed on Jan. 26, 2001, which application is pending and herein incorporated by reference.

### BACKGROUND OF THE INVENTION

1. Field of the Invention

This invention relates generally to the dense packaging of electronic circuitry through the stacking of printed circuit boards (PCB) populated with components, and through the stacking of integrated circuit (IC) chips (aka microcircuits or die). More specifically, the present invention relates to a method making a stack of integrated circuits (ICs) from prepackaged ICs.

2. Description of The Related Art

Of particular interest in the electronic design and manufacturing art, is the high-density packaging of electronic circuitry to yield designs of increased capability. Existing methods for “stacking” electronic circuitry are continuously evolving and improving for better efficiency and reliability.

An early effort to provide a 3-D electronics stack combining different functions, different area electronic chips is illustrated by Kravitz et al., U.S. Pat. No. 3,370,203. That patent shows stacked “frames” having dimensions “such that integrated circuits which have slightly different dimensions can by mounted thereon”, explaining that “integrated circuits from different sources of supply are often advantageously incorporated in a single module.”

Over the last decade and longer, Irvine Sensors Corporation, the assignee of the present invention, has been developing high-density electronic stacking methods. An early process was termed “Silicon Die Stacking,” That method stacked ICs as “bare die” in the form of whole wafers. The wafer stacks were subsequently metalized for electrical interconnection, and the wafer stacks were diced to form connectable die-stacks.

The bare Silicon Die Stacking techniques were problematic for several reasons. Primarily troublesome, is that whole wafers are difficult to obtain because the manufacturers do not want to reveal their yield or expose their built-in test structures that could facilitate reverse engineering of their circuitry. Additionally, a wafer may contain a quantity of defective die, and comprehensive testing procedures are expensive making it even more difficult to purchase pre-tested wafers or bare die. This problem in the field is referred to as obtaining Known Good Die (KGD). Irvine Sensors Corp. developed an improved technology termed “Neo-Die Stacking,” however this method involved stacking bare die, which did not alleviate the problem of obtaining KGD.

Integrated circuit manufactures make readily available prepackaged encapsulated silicon chips that are pre-tested and therefore known good die. Prepackaged chips, also referred to as Plastic Encapsulated Microcircuits (PEMs), can inexpensively be further tested under temperature ranges and sorted. However, stacking prepackaged silicon chips is impractical because they cannot be configured densely enough to meet the requirements of today's applications. Accordingly, Irvine Sensor's Corp. developed further technology which combined old and new methods to reprocess, stack and interconnect pre-packaged silicon chips. Irvine Sensor's has disclosed some of this technology in the published U.S. patent application Ser. No. 09/770,864 entitled “A Stackable Microcircuit Layer Formed From a Plastic Encapsulated Microcircuit and Method of Making the Same.” The content of this published patent application is hereby incorporated by reference in its entirety.

The foregoing patent application details modification and reprocessing of PEMs to form smaller, very thin stackable layers. In one particular embodiment, the PEM is more specifically a memory chip readily available in a plastic encapsulated thin small outline package (TSOP). In brief, the process uses wafer grinding equipment to remove most of the encapsulant material from the top surface of the TSOP, down to the cross section of a gold ball used for electrical connection of the bare silicon. This step leaves a thin layer of encapsulant on the silicon surface, which serves as the insulating surface for metal trace deposition. Grinding is further performed to remove encapsulant from the bottom of the TSOP and to thin the die itself. During this backside grinding step, the leads are also removed. A final dicing step minimizes the layer footprint, while leaving enough of the original TSOP encapsulant around the die edges to provide and insulating surface for bus metalization. The process yields a “stackable layer” that may be stacked with “neo-layers” that are created from bare die.

Although the abovementioned process is largely effective, further methods are needed, as described in the present invention, to balance size and density with manufacturing cost and component availability which can be optimally employed to create a compact, low cost mini-computer.

### BRIEF SUMMARY OF THE INVENTION

In the first aspect, the invention may be regarded as a method of making a stacked assembly of integrated circuits (ICs) comprising the steps of: providing a first encapsulated prepackaged semiconductor chip having internal wire bonds, an encapsulant, and lead material extending from the sides of the chip, removing the lead material and at least part of the encapsulant from the sides, exposing the wire bonds, providing a second encapsulated prepackaged semiconductor chip, one or more internal wire bonds and an encapsulant, exposing the wire bonds of the second encapsulated prepackaged semiconductor chip, stacking the second prepackaged semiconductor chip and subsequent chips onto the first prepackaged semiconductor chip, interconnecting the wire bonds of the stacked semiconductor chips to form electrical connections between all of the stacked chips; and metalizing the electrical connections between the stacked chips to form electrical buses to complete a stacked assembly of ICs.

Additional steps according to this method of the invention include: applying solder balls to the IC stack, mounting the IC stack to a printed circuit board (PCB) with the solder balls, and underfilling the IC stack and PCB to structurally stabilize the IC stack and the PCB. In a separate embodiment, the first and second prepackaged semiconductor chips each have two bare semiconductor chips within each package, the bare semiconductor chips separated by an interposer layer and each bare semiconductor chip has one or more wire bonds. The interposer layer is used to dissipate heat from the stacked IC assembly.

In a second aspect, the invention may be regarded as a method of making a stacked integrated circuit (IC) assembly comprising the steps of: providing a first encapsulated prepackaged semiconductor chip, soldering the first encapsulated prepackaged semiconductor chip to a intermediate PCB, providing a second encapsulated prepackaged semiconductor chip, soldering the second encapsulated prepackaged semiconductor chip to a large PCB, soldering the second encapsulated prepackaged semiconductor chip to the intermediate PCB, attaching a plurality of lead frames to the large PCB.

Additional steps to this aspect of the invention include: providing subsequent encapsulated prepackaged semiconductor chips, and soldering the chips to the stacked IC assembly to make the assembly the desired size.

In a third aspect of the invention, the invention may be regarded as a high-density stacked printed circuit board (PCB) assembly comprising: a plurality of PCBs having one or more through holes extending from the topside to the bottom side, a plurality of discrete components mounted to each PCB on one or more sides, one or more metal conductors extending through the through holes to electrically connect each PCB, one or more encapsulants to occupy the volume between each PCB and each discrete components, and one or more interposer layers arranged within the assembly to dissipate heat generated within the assembly.

In a forth aspect of the invention, another high-density stacked printed circuit board (PCB) assembly is disclosed and claimed. It comprises: a plurality of PCBs having one or more sides, a plurality of discrete components mounted to each PCB on one or more sides, one or more encapsulants to occupy the volume between each PCB and each discrete components, one or more bus bars extending down one or more sides of the plurality of PCBs to electrically connect each PCB, and one or more interposer layers arranged within the assembly to dissipate heat generated within the assembly.

In a fifth aspect, the invention may be regarded as a method of making a stacked assembly of integrated circuits (ICs) from a plurality of encapsulated prepackaged semiconductor chips wherein the resultant assembly has the same footprint as the original plurality of encapsulated prepackaged semiconductor chips comprising the steps of: providing a first encapsulated prepackaged semiconductor chip that conducts electrical signals having one or more lateral edges, soldering the first encapsulated prepackaged semiconductor chip to a PCB interposer layer to form a first subassembly having solder connections, routing the signals to the one or more lateral edges using the PCB interposer layer, providing a second prepackaged semiconductor chip that conducts electrical signals to one or more lateral edges, the chip having a top side and a bottom side, soldering the second prepackaged semiconductor chip to a second PCB interposer layer to form a second subassembly having solder connections, soldering a ball grid array pattern to the bottom side of the second prepackaged semiconductor chip, stacking the first and second subassemblies, and routing electrical signals from the first and second subassemblies to the ball grid array pattern to form the stacked assembly of integrated circuits wherein the assembly has the same footprint as the plurality of encapsulated prepackaged chips. An additional step includes underfilling the solder connections of the first and second subassemblies with epoxy material.

In a sixth aspect, the invention may be regarded as a compact low cost mini-computer comprising a memory stack having one or more lateral edges that includes (a) one or more bus bars extending down the lateral edges of the memory stack, (b) a plurality of prepackaged semiconductor chips each having leads and wire bonds for electrical conductivity wherein the leads are removed, and wherein the wire bonds are connected directly to the one or more bus bars, (c) a top PCB layer connected to the plurality of prepackaged semiconductor chips and connected to the one or more bus bars, (d) a bottom PCB layer connected to the plurality of prepackaged semiconductor chips and connected to the one or more bus bars, and (e) a transceiver layer having one or more transceiver chips mounted to the top PCB layer. In addition to the memory stack, the mini-computer comprises a processor stack having one or more lateral edges and including: (a) a programmable logic device (PLD) layer mounted to a printed circuit board (PCB) layer, (b) a processor layer mounted to the PLD layer, (c) a synchronous dynamic random access memory (SDRAM) layer mounted to the processor layer, (d) a boot flash layer mounted to the SDRAM layer, (e) a discrete component layer having a plurality of crystals, capacitors, and resistors, the discrete component layer mounted to the boot flash layer, and (f) a large PCB board electrically connecting the flash stack and the processor stack to form the minicomputer.

Finally, in a seventh aspect, the invention may be regarded as a method of manufacturing a memory stack (static random access memory, SRAM type, for example) array comprising the steps of: fabricating and testing a predetermined quantity of printed circuit boards (PCBs) having two sides for a predetermined quantity of memory layers for a predetermined quantity of memory stack subassemblies for the memory stack array of a predetermined size, soldering one or more interdigitated capacitors to each side of each PCB, soldering a memory to each side of each PCB using a ball grid array (BGA) pattern, attaching copper shims to each memory, attaching copper sheets to each copper shim to dissipate heat forming a memory layer, stacking multiple memory layers side-by-side to form one memory stack subassembly, the subassembly having voided spaces, encapsulating the voided spaces with epoxy resin, metalizing the memory stack subassembly for electrical interconnection between multiple memory layers, and stacking multiple memory stack subassemblies to form the memory stack array

### BRIEF DESCRIPTION OF THE DRAWINGS

The objects, advantages and features of the present invention will become more apparent to those skilled in the art from the following detailed description, when read in conjunction with the accompanying drawings, wherein:

FIG. 1a is a sectional view of an encapsulated prepackaged semiconductor chip 11 with leads 17 exiting on two sides;

FIG. 1b is a sectional view of an intermediate step of a method embodied by the present invention wherein encapsulated prepackaged semiconductor chips 11 are stacked on top of one another;

FIG. 1c is a sectional view of a stacked assembly of integrated circuits (ICs) wherein the sides of the assembly are metalized to form an electrical bus.

FIG. 2a is a sectional view of an encapsulated prepackaged semiconductor chip 11 that contains two bare semiconductor chips 22 separated by an interposer layer 24;

FIG. 2b is a sectional view of an intermediate step of a method embodied by the present invention wherein encapsulated prepackaged semiconductor chips 11, each containing two bare semiconductor chips, are stacked on top of one another;

FIG. 2c is a sectional view of the stacked encapsulated prepackaged semiconductor chips of FIG. 2b wherein the electrical leads 17 are removed and the sides are metalized to form an electrical bus 18 to complete the stacked assembly of integrated circuits 10;

FIG. 3 is a sectional view of a high-density stacked printed circuit board assembly 30 with plated through-holes 38;

FIG. 4 is a sectional view of a high-density stacked printed circuit board assembly 40 of the present invention that employs metalized bus bars 48 for electrical interconnection;

FIG. 5 is a perspective view of a stacked integrated circuit assembly 50 that employs electrical lead frames 58 for electrical interconnection.

FIG. 6 is a sectioned perspective view of a stacked integrated circuit assembly 50 of FIG. 5;

FIG. 7 is a cross-sectional view of the stacked integrated circuit assembly 50 taken along section line 7-7;

FIG. 8 shows another stacked integrated circuit assembly 80 embodied by the present invention, wherein the stacked assembly 80 has the same footprint as the prepackaged semiconductor chips 86 from which the assembly was made.

FIG. 9 is a block diagram of a low-cost, compact mini-computer embodied by the present invention;

FIG. 10a is a top view of the low-cost, compact mini-computer 900 of the present invention;

FIG. 10b is a profile of the minicomputer 900 with viewable interior of a processor stack 950 and a memory stack 910;

FIG. 11a is a top view of a PLD layer 951 of the present invention;

FIG. 11b is a profile of the PLD layer 951;

FIG. 12a is a top view of a processor layer 953 of the present invention;

FIG. 12b is a profile of the processor layer 953;

FIG. 13a is a top view of a SDRAM layer 954 of the present invention;

FIG. 13b is a profile of the SDRAM layer 954;

FIG. 14a is a top view of a boot flash layer 955 of the present invention;

FIG. 14b is a profile of the boot flash layer 955:

FIGS. 15a and 15b are top and profile views of a discrete component layer 956 of the present invention, respectively;

FIG. 16 is a profile of the processor stack 950 with viewable interior;

FIGS. 17a and 17b are top and profile views of a discrete component layer 915 of the present invention;

FIG. 18 is a profile of the processor stack 950 with viewable interior;

FIGS. 19a through c are a side view (end plate cut away), an end view, and a bottom view, respectively, of a SRAM stack subassemblies of the present invention;

FIG. 20a is top view of a SRAM stack subassemblies;

FIG. 20b is an exploded top view of SRAM stack subassemblies;

FIG. 21 is a block diagram of the process for making a SRAM stack array of the present invention;

FIG. 22 a through e are illustrations of SRAM subassembly during selected stages of the process of FIG. 21;

FIG. 23 a through c is an illustration of the SRAM stack array of the present invention.

### DETAILED DESCRIPTION OF THE PREFERRED EMBODIMENTS

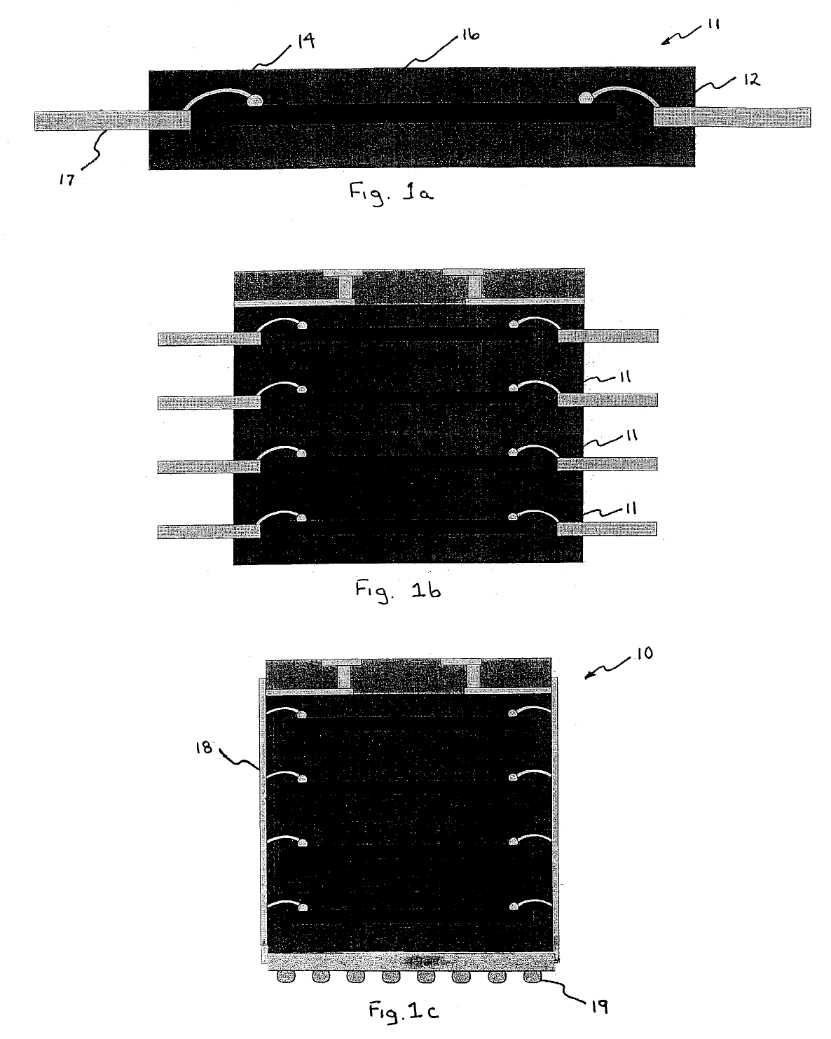

Referring initially to FIG. 1a through c, an encapsulated prepackaged semiconductor chip 11, and more specifically a flash memory thin small outline package (TSOP) is shown with leads 17 exiting both sides. In a method of the invention, the TSOPs are stacked as shown in FIG. 1b. The sides of the stack with the TSOP leads 17 are ground to the point that the lead material is removed and the ends of the internal bonded wires are exposed. As illustrated in FIG. 1c, metalization is then applied to form busses 18 to interconnect the wires and the top and bottom layers which may be a separate transceiver layer or a PCB layer, for example. Solder balls 19 are included as a final step, to provide means to connect the stack to a primary PCB (not shown) such as that of a computer. The finished structure has the memory capacity of an individual TSOP times the number layers in the stack.

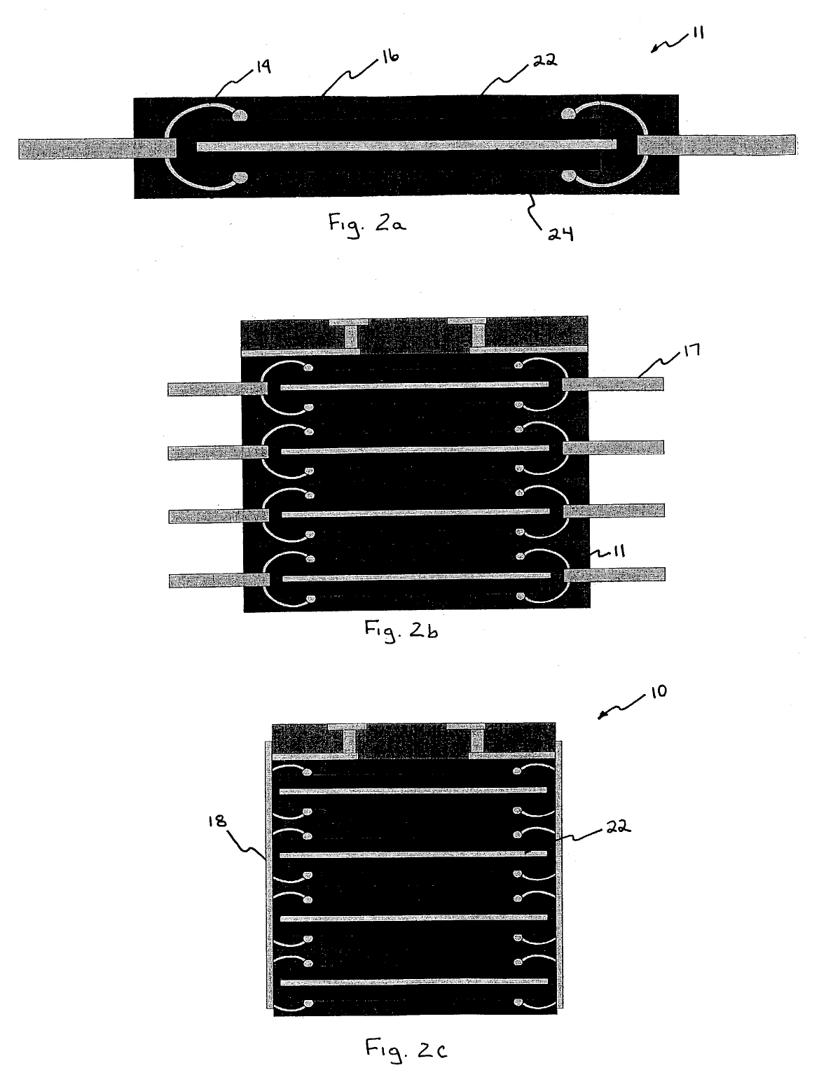

FIGS. 2a through 2c shows the same process as in FIGS. 1a through 1c, however TSOP 11 contains more than one bare semiconductor chip 22 internally. Specifically, two separate bare semiconductor chips 22 are contained within the TSOP 11 in a back-to-back configuration and separated by interposer layer 24. The processes of FIGS. 1 and 2 do not employ “thinning” the TSOP from the top and bottom and subsequent connecting layers electrically via metal film traces as in the prior art. Instead the wire bonds 14 are exposed from the sides and not the top of the TSOP 11. While not providing the increased density advantages of thinning, exposing the wire bonds 14 from the sides, efficiently balances size and manufacturing cost requirements.

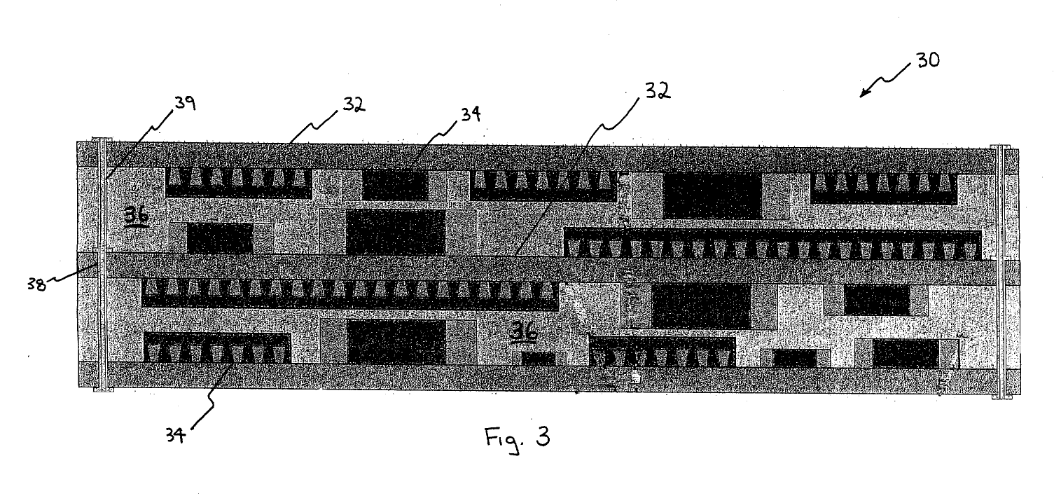

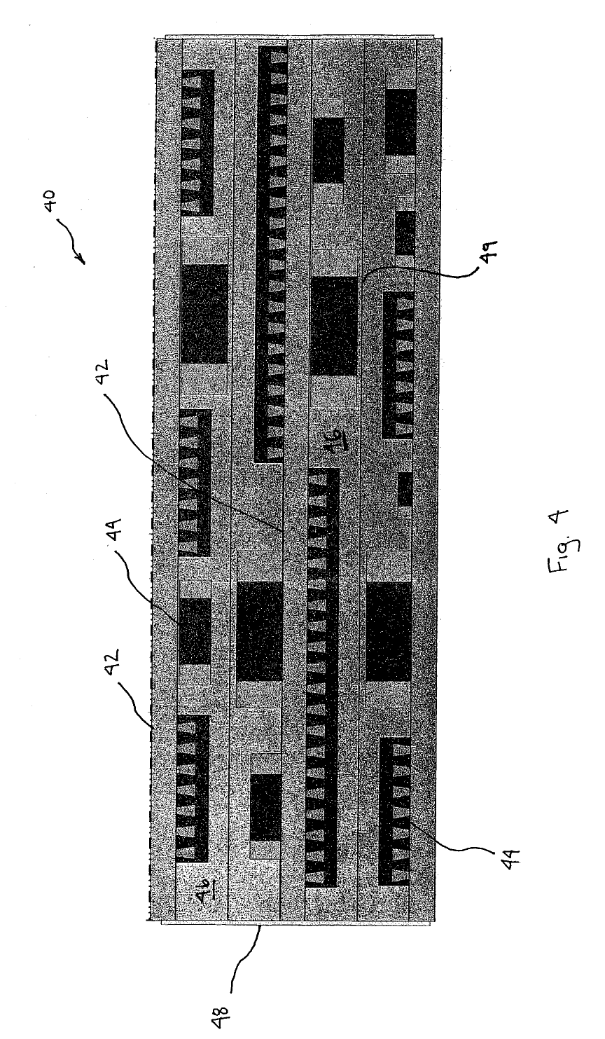

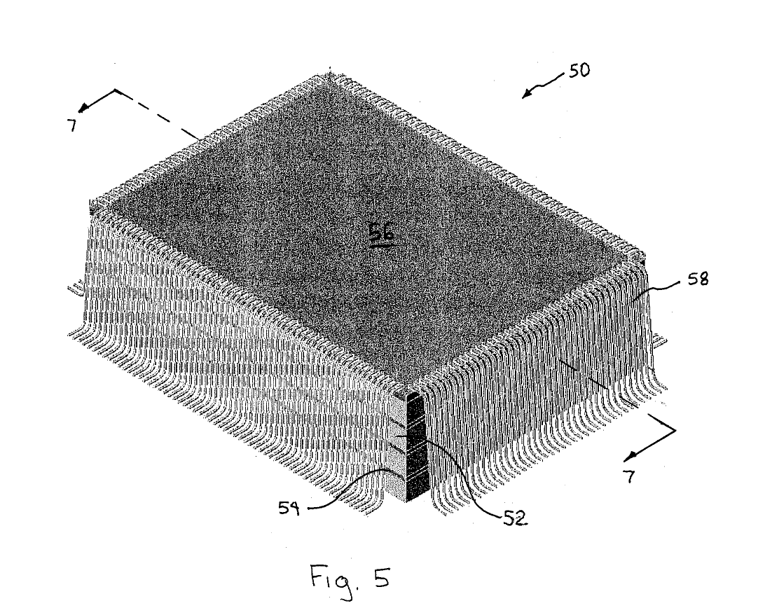

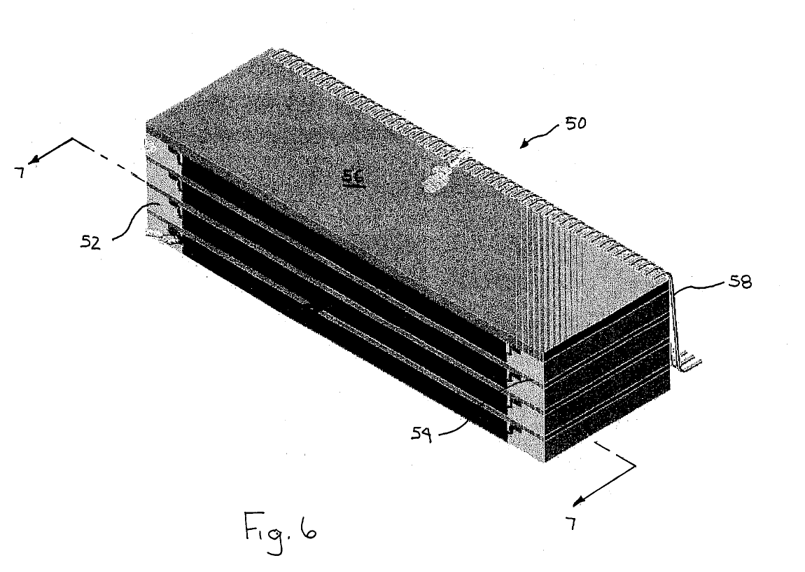

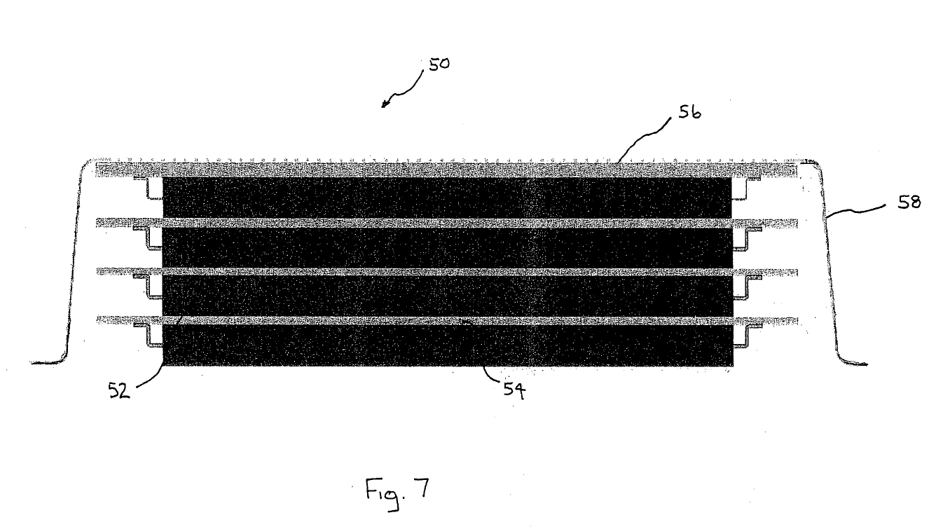

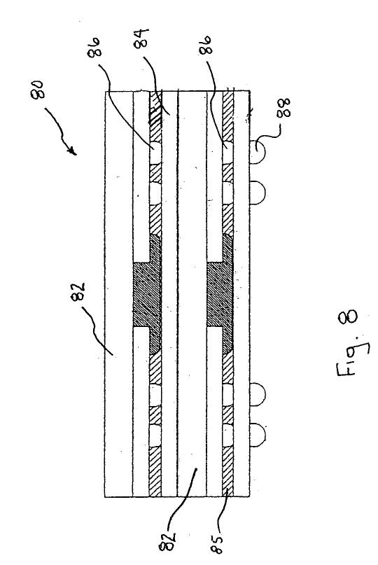

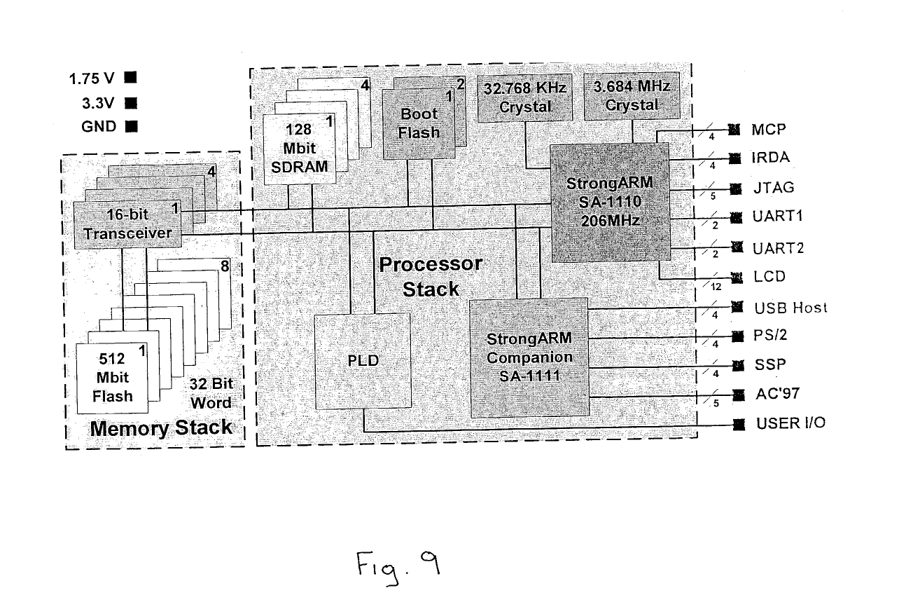

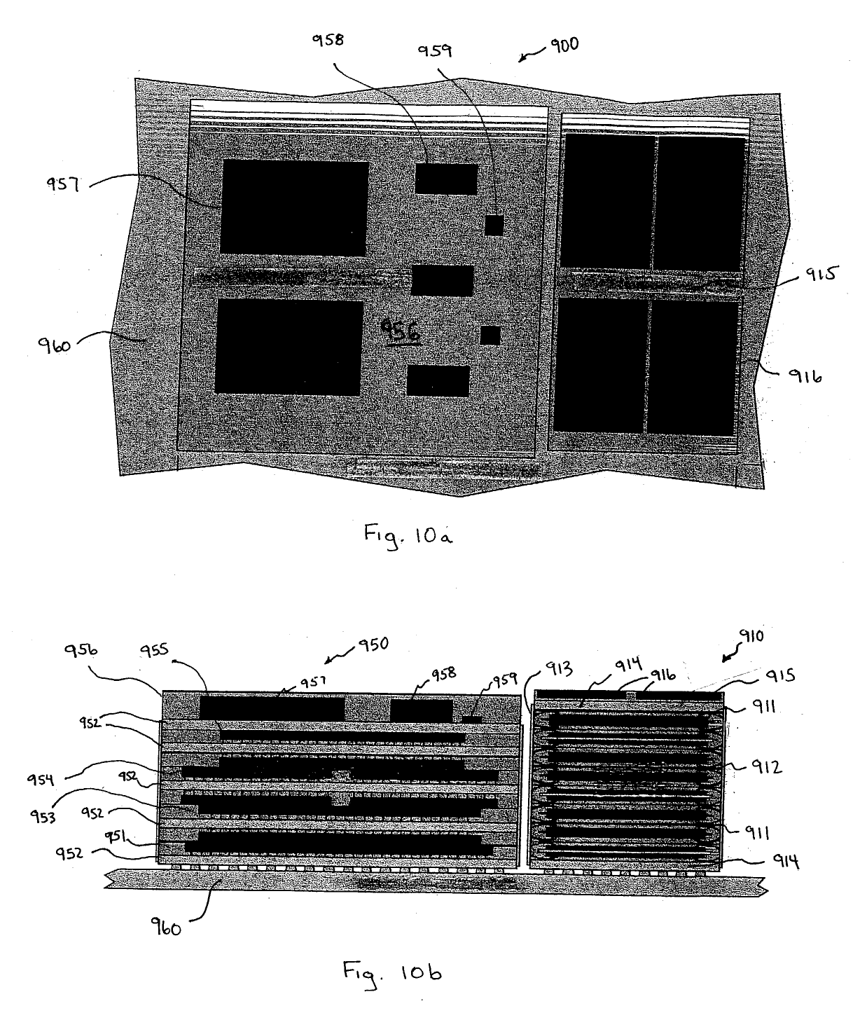

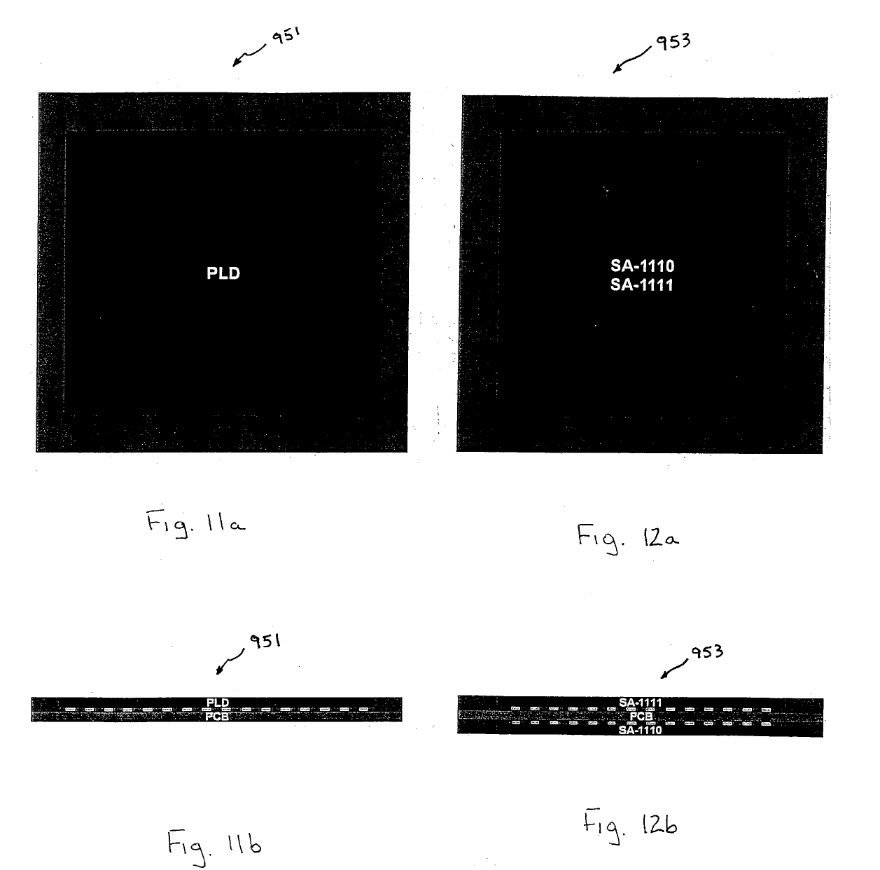

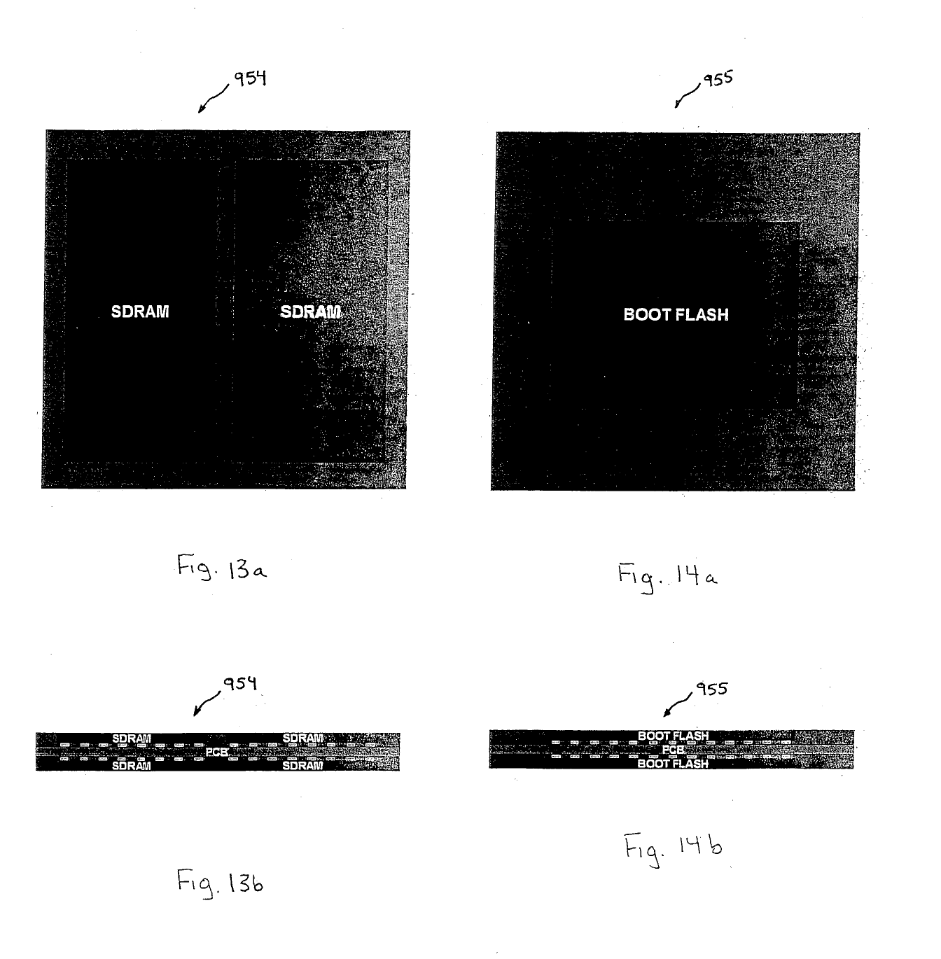

FIG. 3 illustrates a high density packaging technique using primarily standard printed circuit board (PCB) fabrication manufacturing technology. Large PCBs can contain repeated patterns of a portion of a circuit for manufacturing multiple assemblies 30, and some PCBs 32 contain components 34 on both sides. In a method of the invention, the PCBs 32 are populated with components 34, on one or two sides, using surface mount soldering and a high-temperature solder. Several PCBs of different designs, each containing part of the entire circuit, are stacked together, and all of the space between PCBs is filled with an encapsulant material 36. The assembly 30 is further processed to add plated through holes 38 between PCBs 32 and to form a final metal pattern on the exterior boards. As a general design parameter, the through hole 38 diameter should be approximately equal to about 10% of the board thickness. The assembly 30 may then be cut into individual stacked circuits. Additionally, further components and connectors can be soldered to the exterior boards using standard solder. The final step in the method is testing.

FIG. 4 illustrates an alternative embodiment to the invention illustrated in FIG. 3. A high-density stacked printed circuit board assembly 40 of the present invention alternatively employs metalized bus bars, instead of plated through holes 48, for electrical interconnection. Other than this difference, the processes of the two embodiments are identical.

FIGS. 5 through 7 illustrate stacking encapsulated prepackaged semiconductor chips 52 with leadered parts as in other embodiments, however this alternate method uses additional PCB material and lead frames 58 to achieve the desired configuration. This method is particularly suitable for dual-port static random access memory (DPSRAM) and SRAM. The encapsulated prepackaged chips are soldered to intermediate PCBs 54 to form layers. The final layer is soldered to a large PCB. By way of example only, the large PCB 56 may be 0.02 inches thick and the intermediate PCBs 54 may be 0.01 inches thick. A plurality of lead frames 58 are employed to attach the large PCB to a prospective customer's board.

FIG. 8 illustrates a method of the present invention as applied to encapsulated prepackaged chips 82 that contain fine ball grid array FBGA configurations 86. A significant advantage to this configuration is that the final stacked assembly with have the same footprint as the original FBGA packages 82. This allows anticipation of newer technology because an obsolete stack can be replaced with higher capability components with the same footprint as they become available. In this method, a first encapsulated prepackages chip 82 (FBGA type, for example) is soldered 86 to a PCB interposer layer 84 that routes signals to two edges. Next, separately solder 86 a second FBGA 84 to a second PCB interposer layer 84 that routs signals from two edges to a ball grid array pattern 88. The aforementioned PCB solder connections 86 are finally underfilled with epoxy resin for insulation and stability.

FIGS. 9 through 18 collectively illustrate a compact, low-cost minicomputer where various method and structure of the present invention are employed. FIG. 9 is a block diagram of the compact, low-cost minicomputer embodied by the present invention. The computer consists of two stacks, a processor stack 950, and flash memory storage stack 910. By way of example only, the flash memory storage stack 910 is a 0.5 GB solid-state hard drive, and the processor stack 950 implements a 32-bit Intel® StrongARM® computer system running Linux operating system. Support for the LCD, mouse, keyboard, and external I/O is provided.

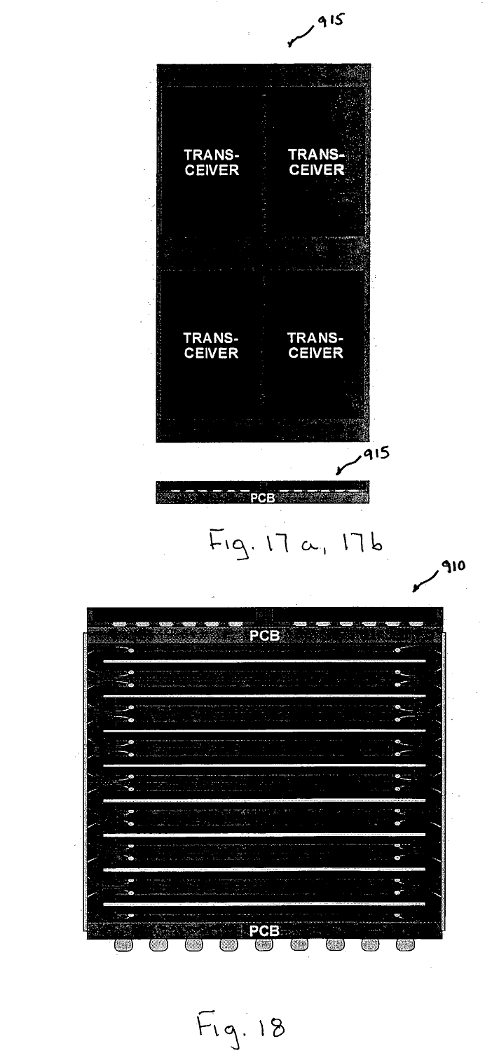

The processor stack 951 construction is shown in FIG. 16 and the individual layers are shown in FIGS. 11a through 15b. Other than the two crystals, three capacitors, and two resistors, all of the processor component layers are available in ball grid array (BGA) packages. The typical BGA package construction has the bare semiconductor chip flip-chip mounted to a carrier (i.e. PCB), encapsulated, and then solder balls 945 are attached to the PCB for interconnection to the next layer. This internal construction allows thinning the package and removing much of the backside of the semiconductor from the chip without disturbing the chip interconnect surface.

For the Programmable Logic Device (PLD) layer 951, the basic process is to perform a BGA solder mounting of many PLDs onto a large PCB (for mass production) and then underfill and pot the connection for insulation and stability. The resulting large panel is then cut into sections, thinned, and then diced into individual layers. The finished PLD layer is shown in FIGS. 11a and 11b.

The processor layer 953 shown in FIGS. 12a and 12b contains, by way of example, the StrongARM processor (SA-1110) and the StrongARM companion chip (SA-1111). The construction of the process layer 953 is similar to that of the PLD layer 951, except that the two components are mounted on either side of the PCB and the mounting, underfill, pot, and thinning steps are accomplished for both sides the PCB.

The synchronous dynamic random access memory (SDRAM) 954 and Boot Flash 955 layers are shown in FIGS. 13a and 13b, and 14a and 14b, respectively. These layers are two-sided like the process layer. Additionally, the SDRAM layer has two chips on each side of the PCB.

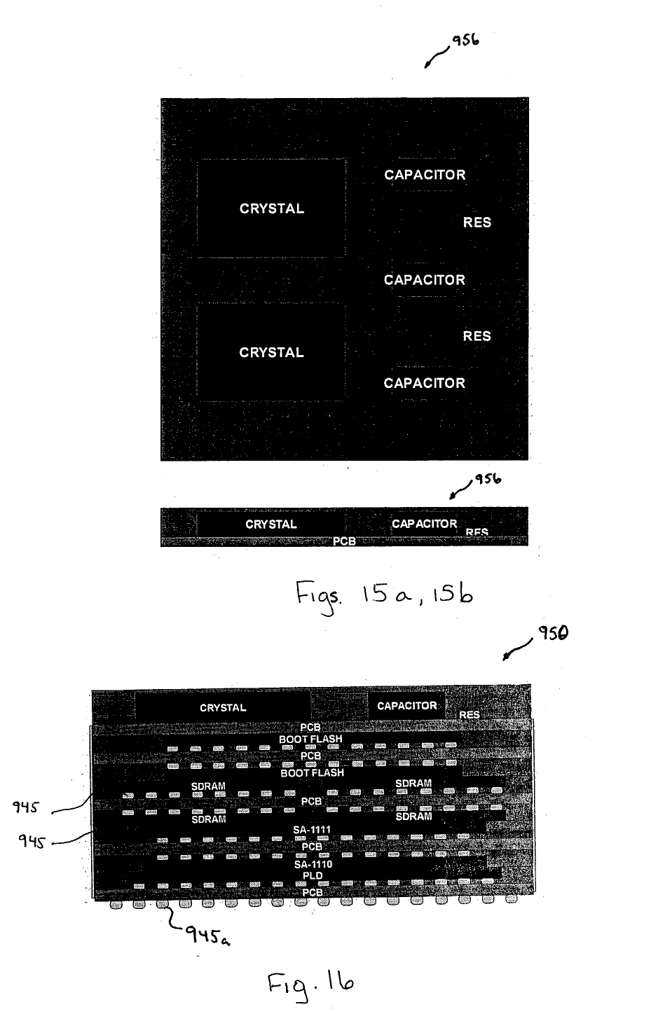

The final layer in the processor stack is the discrete component layer 956 as shown in FIGS. 15a and 15b. It contains seven semiconductor, discrete surface-mount components (two crystals, three capacitors, and two resistors), by way of example. The construction is similar to the one-sided PLD layer 951 except thinning of the discrete layer 956 leaves potting material above the components.

For the processor stack 950, again illustrated in FIG. 16, the five layers are laminated together and interconnected using stacking technology. Metalization is added to the two sides of the stack to complete the interconnection between layers, bringing all input/output signals to the PLD PCB, to which PLD PCB solder balls are subsequently added. The exposed metal on the busses is coated for protection at the next level of assembly.

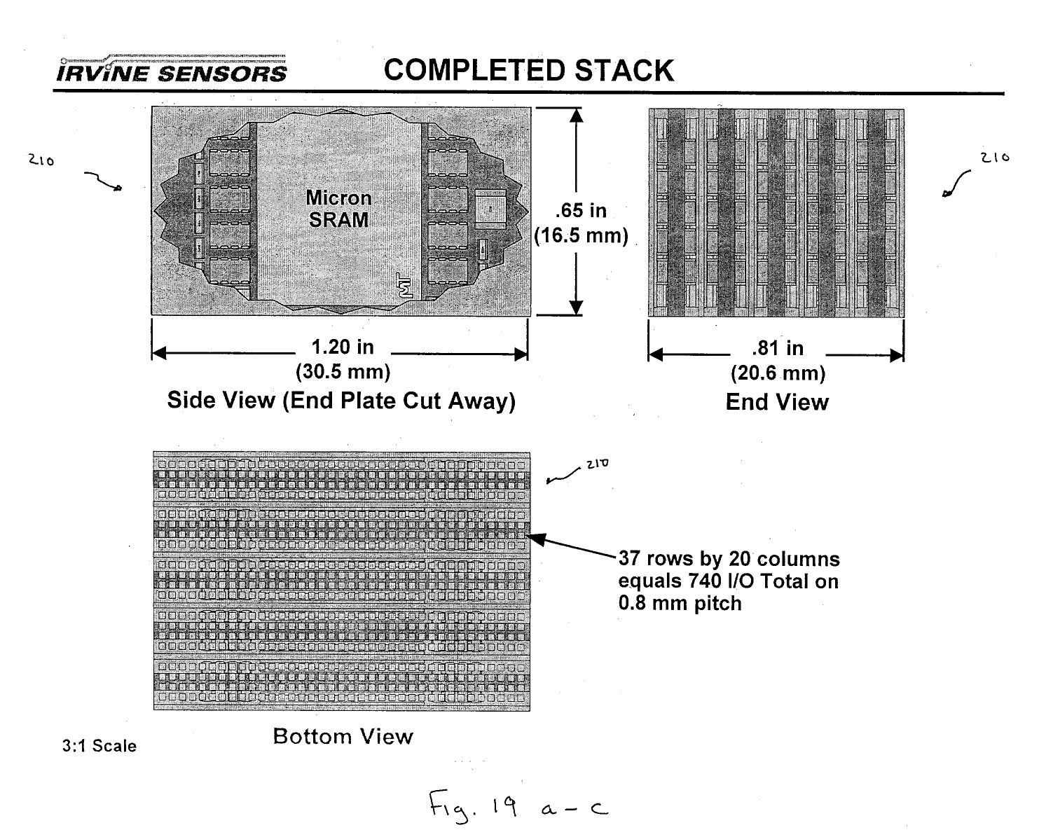

Now referring to FIG. 18, the flash memory stack contains eight large-capacity flash memory chips 911 and four transceiver chips 916. The layer for the transceivers 915, as shown in FIGS. 17a and 17b, is similar to the PLD layer 951 in the processor stack 950. The flash memory is stacked using a method of the present invention as detailed in FIGS. 1 and 2. The flash chips come in TSOPs with leads exiting on two sides. The bare semiconductor inside may be a single chip (as in FIG. 1) or two separate chips in a back-to-back configuration (as in FIG. 2). The TSOPs 911 are laminated directly with the transceiver layer and a top PCB layer 914a. The sides of the stack with the TSOP leads are ground to the point where the lead material is removed and the ends of the internal bonded wire are exposed. The metalization is then applied to the busses to interconnect the wires, the traces of the transceiver layer 915, and the bottom PCB 914b. As with the processor stack, the busses are coated and solder balls added as a final step.

The manufacturing process for the stacks are optimized for mass production. For all but the flash memory chips 911, the PCB fabrication, and encapsulation processes are performed in large area panels. The panels are quartered for thinning, then cut into individual layers or strips of layers for stacking. Layers are laminated into cubes of multiple stacks, which are separated into individual stacks after metalizing the busses. This approach to layer and stack fabrication largely avoids the processing of individual components/layers and lends itself to automation. The technique of stacking flash memory avoids layer fabrication altogether.

Most of the manufacturing can be easily transitioned to contract manufacturers because many of the processes are standard (e.g., PCB fabrication, surface-mount soldering, underfill, and thin film deposition). This results in flexibility, lower cost and a rapid ramping to high volume without a large capital investment. For the reasons stated above, the design approach provides for a cost effective and producible product.

As shown in FIGS. 10a and 10b, the intent is for the user to interconnect the two stacks as part of integration into the application platform. The user PCB 960 would supply the required power (1.75 V, 3.3 V, and ground) and interconnection to the import/export hardware. In sum, an extremely compact, highly capable, and low cost computer can be constructed using standard parts and mostly standard assembly processes. The stacked construction is inherently rugged and the assembly and interconnection processes used have been demonstrated to be highly reliable, making the product suitable for a wide range of applications.

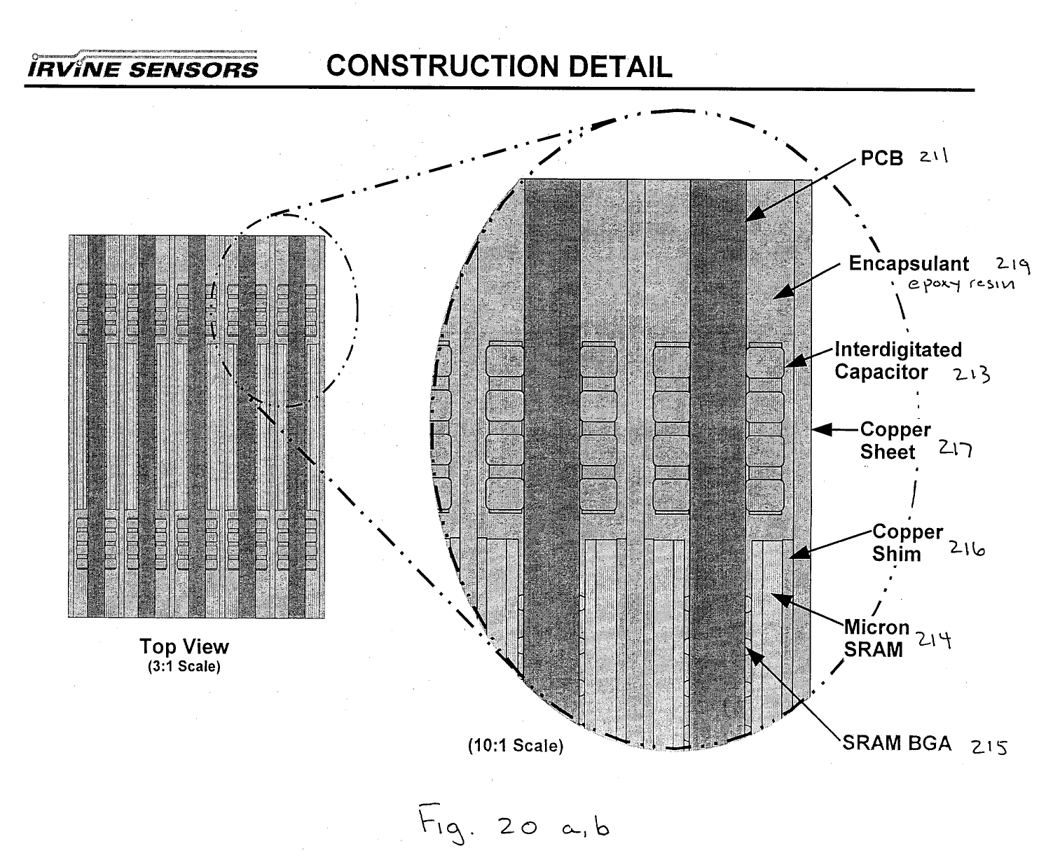

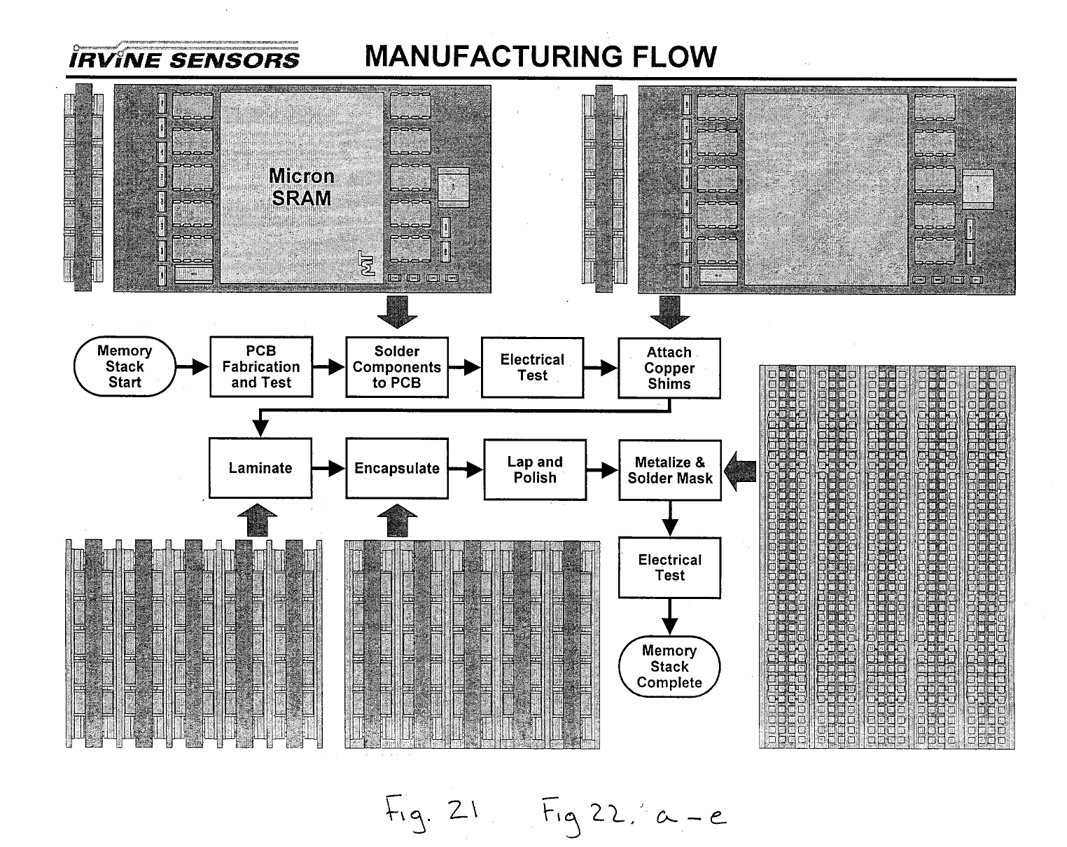

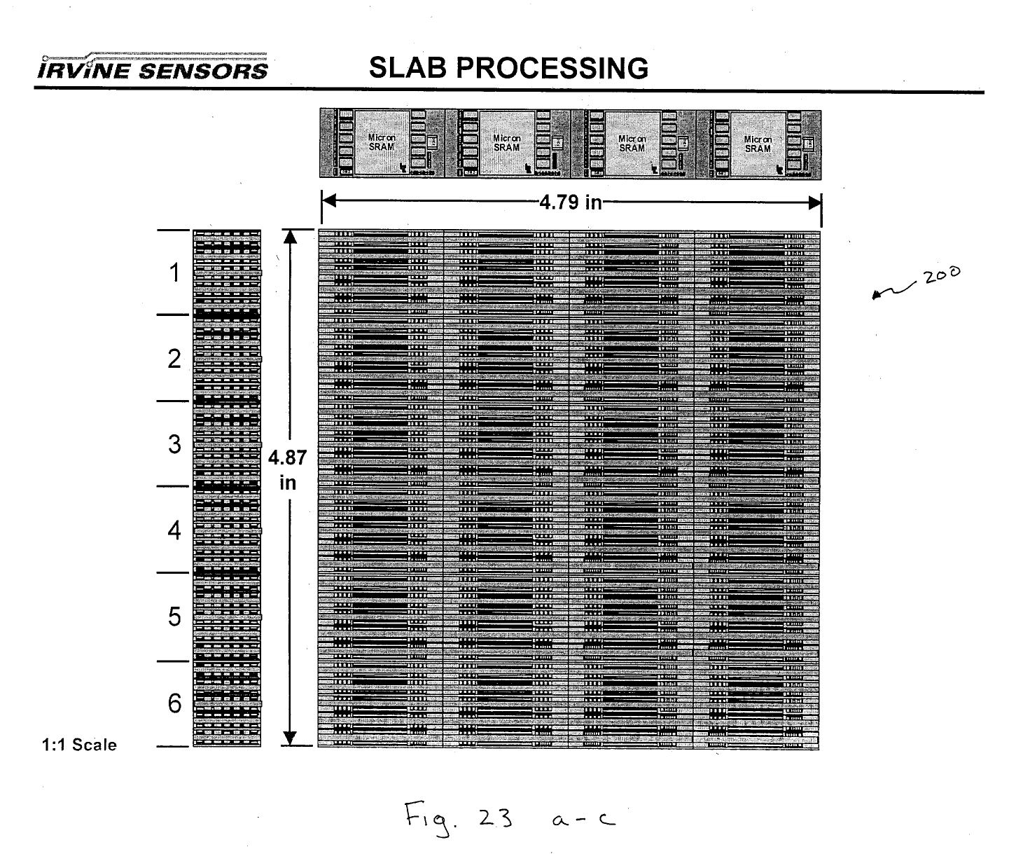

FIGS. 19 through 23c illustrate the process used to fabricate a large capacity memory (SRAM type for example) stack array 200. The complete array 200 is illustrated in FIG. 23. The array 200 is made from twenty four memory stack subassemblies 210. A subassembly 210, is illustrated more specifically as a Micron SRAM S-Neo Stack, however the integrated circuit function is unimportant to the invention. Each subassembly 210 contains ten memory chips 214.

In this design, the copper shims 216 and copper sheets 217 provide excellent heat transfer characteristics without shorting circuitry. The copper sheets 217 are physically located between layers and thermal management is accomplished by drawing the heat from the top of each chip. Heat from one side of the memory chip 214 will go directly into the copper sheets 217, while on the other side, heat from the leads or BGA 215 is dissipated into ground planes in the PCB 211. These dual paths quickly spread the heat away from chips being exercised. Since only portions of the full array are exercised at one time, spreading the heat into the whole array and away from hot spots is essential. This makes managing the dissipation from the module relatively simple while keeping the junctions relatively cool. Once laminated (FIG. 22c), the subassembly 210 is encapsulated with an epoxy material that is chemically similar to the compound used to encapsulate the memory chips. The encapsulant makes the module rugged, and the combination of materials used result in a composite thermal expansion coefficient very close to a typical host PCB. This means that the BGA used to attach the module to the host PCB will undergo a minimum of stress.

While the invention has been illustrated and described by means of specific embodiments, it is to be understood that numerous changes and modifications may be made therein without departing from the intent and scope of the invention as defined in the appended claims.

We claim:

1. A method of making a stacked assembly of integrated circuits (ICs) comprising the steps of:
providing a first encapsulated prepackaged semiconductor chip having one or more sides, one or more internal wire bonds and an encapsulant,
removing at least part of the encapsulant from the sides, exposing the wire bonds,
providing a second encapsulated prepackaged semiconductor chip having one or more sides, one or more internal wire bonds and an encapsulant,
exposing the wire bonds of the second encapsulated prepackaged semiconductor chip, stacking the second prepackaged semiconductor chip onto the first prepackaged semiconductor chip; and
interconnecting the wire bonds of the first prepackaged semiconductor chip and the second prepackaged semiconductor chip to form one or more electrical connections between the first and second prepackaged semiconductor chip to form a stacked assembly of ICs.

2. The method of claim 1 wherein the first and second prepackaged semiconductor chips have electrical lead material extending from the sides and further comprising the step of removing the electrical lead material.

3. The method of claim 1 further comprising the step of metalizing the electrical connections between the first and second prepackaged semiconductor chip to form one or more electrical buses.

4. The method of claim 1 wherein the electrical busses have undesired exposed metal and further comprising the step of coating the exposed metal with and insulating material for electrical insulation and protection.

5. The method of claim 1 and further comprising the step of adding subsequent prepackaged semiconductor chips to the first and second prepackaged chips to form an IC stack from a plurality of prepackaged chips.

6. The method of claim 1 and further comprising the steps of:
applying solder balls to the IC stack, and
mounting the IC stack to a printed circuit board (PCB) with the solder balls.

7. The method of claim 6 and further comprising the step of underfilling the IC stack and PCB to structurally stabilize the IC stack and the PCB.

8. The method of claim 1 wherein the first and second prepackaged semiconductor chips each have two bare semiconductor chips within each package, the bare semiconductor chips separated by an interposer layer and each bare semiconductor chip having one or more wire bonds.

9. The method of claim 8 wherein the interposer layer is used to dissipate heat from the stacked IC assembly.

10. A method of making a stacked integrated circuit (IC) assembly comprising the steps of:
providing a first encapsulated prepackaged semiconductor chip,
soldering the first encapsulated prepackaged semiconductor chip to a intermediate PCB,
providing a second encapsulated prepackaged semiconductor chip,
soldering the second encapsulated prepackaged semiconductor chip to a large PCB,
soldering the second encapsulated prepackaged semiconductor chip to the intermediate PCB, and
attaching a plurality of lead frames to the large PCB.

11. The method of claim 10 further comprising the steps of:
providing subsequent encapsulated prepackaged semiconductor chips, and
soldering the chips to the stacked IC assembly to make the assembly the desired size.

12. A high-density stacked printed circuit board (PCB) assembly comprising:
a plurality of PCBs having one or more sides including a topside and a bottom side and having one or more through holes extending from the topside to the bottom side,
a plurality of discrete components mounted to each PCB on one or more sides,
one or more metal conductors extending through the through holes to electrically connect each PCB, and
one or more encapsulants to occupy the volume between each PCB and each discrete components.

13. The high-density stacked printed circuit board (PCB) assembly of claim 12 further comprising one or more interposer layers arranged within the assembly to dissipate heat generated within the assembly.

14. A high-density stacked printed circuit board (PCB) assembly comprising:
a plurality of PCBs having one or more sides,
a plurality of discrete components mounted to each PCB on one or more sides,
one or more encapsulants to occupy the volume between each PCB and each discrete components, and
one or more bus bars extending down one or more sides of the plurality of PCBs to electrically connect each PCB.

15. The high-density stacked printed circuit board (PCB) assembly of claim 14 further comprising one or more interposer layers arranged within the assembly to dissipate heat generated within the assembly.

16. A method of making a stacked assembly of integrated circuits (ICs) from a plurality of encapsulated prepackaged semiconductor chips wherein the resultant assembly has the same footprint as the original plurality of encapsulated prepackaged semiconductor chips comprising the steps of:
providing a first encapsulated prepackaged semiconductor chip that conducts electrical signals having one or more lateral edges,
soldering the first encapsulated prepackaged semiconductor chip to a PCB interposer layer to form a first subassembly having solder connections,
routing the signals to the one or more lateral edges using the PCB interposer layer,
providing a second prepackaged semiconductor chip that conducts electrical signals to one or more lateral edges, the chip having a top side and a bottom side,
soldering the second prepackaged semiconductor chip to a second PCB interposer layer to form a second subassembly having solder connections,
soldering a ball grid array pattern to the bottom side of the second prepackaged semiconductor chip.
stacking the first and second subassemblies, and
routing electrical signals from the first and second subassemblies to the ball grid array pattern to form the stacked assembly of integrated circuits wherein the assembly has the same footprint as the plurality of encapsulated prepackaged chips.

17. The method of claim 16 further comprising the step of underfilling the solder connections of the first and second subassemblies with epoxy material.

18. A compact low cost mini-computer comprising:
a memory stack having one or more lateral edges including:
one or more bus bars extending down the lateral edges of the memory stack,
a plurality of prepackaged semiconductor chips each having leads and wire bonds for electrical conductivity wherein the leads are removed, and wherein the wire bonds are connected directly to the one or more bus bars,
a top PCB layer connected to the plurality of prepackaged semiconductor chips and connected to the one or more bus bars,
a bottom PCB layer connected to the plurality of prepackaged semiconductor chips and connected to the one or more bus bars,
a transceiver layer having one or more transceiver chips mounted to the top PCB layer,
a processor stack having one or more lateral edges including:
a programmable logic device (PLD) layer mounted to a printed circuit board (PCB) layer,
a processor layer mounted to the PLD layer,
a synchronous dynamic random access memory (SDRAM) layer mounted to the processor layer,
a boot flash layer mounted to the SDRAM layer,
a discrete component layer having a plurality of crystals, capacitors, and resistors, the discrete component layer mounted to the boot flash layer, and
a large PCB board electrically connecting the flash stack and the processor stack to form the minicomputer.

19. A method of manufacturing a memory stack array comprising the steps of:
fabricating and testing a predetermined quantity of printed circuit boards (PCBs) having two sides for a predetermined quantity of memory layers for a predetermined quantity of memory stack subassemblies for the memory stack array of a predetermined size,
soldering one or more capacitors to each side of each PCB,
soldering a memory to each side of each PCB using a ball grid array (BGA) pattern,
attaching copper shims to each memory,
attaching copper sheets to each copper shim to form a memory layer,
stacking multiple said memory layers side-by-side to form one said memory stack subassembly of said predetermined quantity of layers, said subassembly having voided spaces,
encapsulating the voided spaces with epoxy resin,
metalizing the memory stack subassembly for electrical interconnection between said multiple memory layers, and
stacking multiple memory stack subassemblies to form the memory stack array.

20. The method of claim 19 further comprising, the step of using the copper sheet to dissipate heat.
